(19) United States
(12) Patent Application Publication
(10) Pub. No.: US 2008/0078935 A1
(43) Pub. Date: Apr. 3, 2008

(54) Imaging apparatus

(76) Inventor: Dennis Johannes Adrianus Bijwaard, Enschede (NL)

Correspondence Address: Lucent Technologies Inc.;Docker Administrator - Room 3J-219, 101 Crawfords Corner Road, Holmdel, NJ, 07733-3030, US

(21) Appl. No.: 11/541,033

(22) Filed: Sep. 28, 2006

(51) Int. Cl. H01L 25/00

(52) U.S. Cl. 250/332

(57) ABSTRACT

Imaging apparatus comprises a plurality of radiation-sensitive detectors, such as arrays of CCDs 2, that are arranged to define a curved imaging region 3 at which incident radiation from a scene surrounding the detectors is detected. A processor 4 for combining image information from the detectors is used to obtain a three-dimensional image of the surrounding scene.

### FIELD OF THE INVENTION

The present invention relates to imaging apparatus, and more particularly, but not exclusively, to apparatus capable of imaging in three dimensions for surveillance purposes.

### BACKGROUND OF THE INVENTION

It is known to obtain three-dimensional, or stereoscopic, images of a scene by using two spatially separated cameras. In another approach, a single camera is moved and images recorded from different positions to enable a three dimensional image to be derived. A single camera may be static and arranged to point upwards and to receive light spread horizontally via a mirror to again provide spatially differentiated image information. Solutions based on these types of approaches tend to be complex and are often expensive.

### BRIEF SUMMARY OF THE INVENTION

According to an aspect of the invention, imaging apparatus comprises a plurality of radiation-sensitive detectors that are arranged to define a curved imaging region. Incident radiation from a scene surrounding the detectors is detected at the imaging region. A processor is used to combine image information from the detectors to obtain an image of the surrounding scene. This could be by stitching together imaging information, essentially a two-dimensional technique, to obtain a panorama picture of the scene that is curved, or spherical, and thus in three-dimensions. For a stereoscopic image, the techniques used for producing a stereoscopic image from two cameras may be applied to a larger number of detectors of the curved imaging region in accordance with the invention. Processing the image information to obtain a stereoscopic image enables the location of objects in the imaged scene to be calculated, if the position one of the objects is known relative to the detectors.

According to another aspect of the invention, imaging apparatus comprises a plurality of radiation-sensitive detectors that are arranged to define a curved imaging region at which incident radiation from a scene surrounding the detectors is detected. The imaging region is extensive in a substantially curved plane and the field of view of the detectors is outward from the curved plane. The substantially curved plane may be smoothly curved or polygonal. The imaging region could be cylindrical, part-spherical or a full sphere, for example.

The detectors could be distributed over the entire imaging region, which may enable moving parts to be minimized, reducing expense and facilitating real-time video creation from the image information gathered at the detectors, as it permits a good frame rate to be achieved. In another embodiment, the detectors are moved to define the curved imaging region. For example, a linear array of imaging sensors may be arranged parallel to an axis and the array moved along a curved path about the axis to define the imaging region. The linear array could be mounted on a cylindrical drum, which is rotatable about its axis so that the region is cylindrical.

The detectors may comprise a plurality of CCD arrays, or be based, for example, on CMOS technology or be made up of an array of individual photosites, or some other suitable type of detector technology. The detector array may be sensitive to radiation in the visible part of the spectrum, or in the infrared part, or be sensitive to wavelengths including both visible and infrared parts, for example. In another embodiment, the detectors are sensitive to microwave radiation. In some embodiments, it may be possible to employ a CCD array designed for use in flatbed scanners, and thus already available at relatively low cost.

In another embodiment, the curved imaging region is circular, or elliptical, and is extensive in a substantially flat plane. The diameter of the circle, or the axes of an ellipse, may be increased to obtain greater spatial separation and hence potentially increased three-dimensional image quality. In another embodiment, detectors are arranged in a plurality of curved arrays, each array being extensive in a substantially flat plane. The arrays are stacked parallel to one another in a direction normal to their planes.

According to another aspect of the invention, surveillance equipment includes imaging apparatus which comprises a plurality of radiation-sensitive detectors that are arranged to define a curved imaging region at which incident radiation from a scene surrounding the detectors is detected. A processor combines image information from the detectors to obtain a curved image of the surrounding scene.

### BRIEF DESCRIPTION OF THE DRAWINGS

Some embodiments in accordance with the present invention will now be described by way of example only, and with reference to the accompanying drawings, in which:

FIG. 1 schematically illustrates imaging apparatus in accordance with the invention;

FIG. 2 schematically illustrates imaging apparatus having a stacked arrangement of detectors in accordance with the invention;

FIG. 3 schematically illustrates imaging apparatus in accordance with the invention in which a cylindrical imaging region is defined;

FIG. 4 schematically illustrates imaging apparatus in accordance with the invention in which a linear array of detectors is included;

FIG. 5 schematically illustrates imaging apparatus having a part spherical imaging region in accordance with the invention;

FIG. 6 schematically illustrates another imaging apparatus having a part spherical imaging region in accordance with the invention;

FIG. 7 schematically illustrates another imaging apparatus in accordance with the invention; and

FIG. 8 schematically illustrates imaging apparatus in accordance with the invention in which detectors are distributed in a spherical pattern.

### DETAILED DESCRIPTION

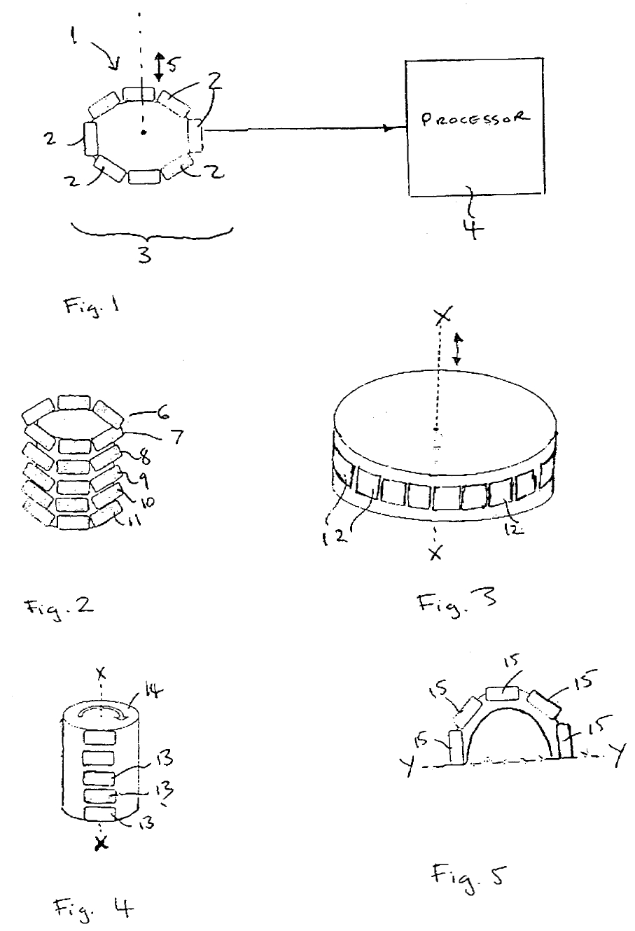

With reference to FIG. 1, imaging apparatus 1 includes an arrangement of CCD arrays 2 arranged end to end in a circular or elliptical pattern to form a curved imaging region 3. Each of the CCD arrays 2 comprises a substantially rectangular radiation sensitive area made up of rows and columns of pixels. Electrical charge is generated in response to incident visible light, to give an electronic representation of the scene being viewed. The collected electrical charge is clocked from each CCD array 2 and applied to a processor 4 which creates an image of the scene as viewed by each of the CCD arrays, and then stitches them together so as to produce a curved panoramic representation of the scene in all directions. The arrangement of CCD arrays 2 may optionally be moved in a direction normal to the plane in which they lie, the direction being shown by the arrow 5. This increases the vertical extent of the imaging region defined by the CCD arrays, and hence enables more image information to be collected.

In each of the embodiments described with reference to the following Figures, a processor is included similar to that shown in FIG. 1, but these have been omitted from the following Figures for the purpose of conciseness.

With reference to FIG. 2, several arrangements 6, 7, 8, 9, 10 and 11 of detector arrays, each similar to that shown in FIG. 1, are stacked parallel to one another. The CCD arrays are inclined slightly with respect to the plane. If the arrays are spaced far enough apart, there will be little or no shadowing of one array by an adjacent one, but if shadowing does occur, it may be digitally removed from the image during the image processing.

With reference to FIG. 3, a plurality of CCD arrays 12 are arranged in a circle, but, in contrast to the arrangement shown in FIG. 1, their radiation sensitive areas are substantially normal to the plane of the circle, giving a cylindrical imaging region. The array may be moved in a direction along the longitudinal axis X-X to increase the size of the imaging region.

With reference to FIG. 4, a linear array of CCDs 13 is fixed on a cylindrical drum 14 parallel to its longitudinal axis X-X. The drum is rotated about the axis X-X in the direction shown by the arrow so that the linear array 13 defines a cylindrical imaging region.

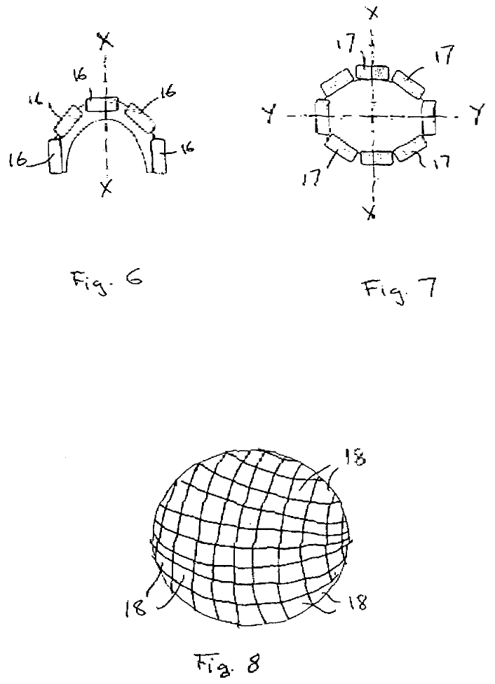

With reference to FIG. 5, in another imaging apparatus, an arrangement of CCD arrays 15 is arranged in a half-circle, or half-ellipse, configuration. The array is rotatable about an axis Y-Y to define a curved imaging region. In a variant, a quarter-circle or quarter-ellipse arrangement may be used.

With reference to FIG. 6, in another imaging apparatus, an arrangement of CCD arrays 16 is again arranged in a half-circle, or half-ellipse, configuration. The array is rotatable about an axis X-X through the center of the arrangement to define a curved imaging region. In a variant, a quarter-circle or quarter-ellipse arrangement may be used.

With reference to FIG. 7, in another imaging apparatus, an arrangement of CCD arrays 17 is rotatable about either or both of two orthogonal axes X-X and Y-Y.

With reference to FIG. 8, an array of detectors 18 is distributed over a spherical support, to give a wide field of view. In other embodiments, only a half-sphere, is defined by the array, to give only hemispherical coverage, or may be rotatable to provide a completely spherical field of view. Other fractions of a spherical array may be used, for example, a quarter-sphere.

In the arrangements described above, where a detector array is moved about an axis, a complete revolution need not be described if full coverage is not required.

The imaging apparatus described with reference to any of the Figures may be surveillance equipment, such as security cameras, and the image information may be used to generate real time video imaging in all directions, for example.

The present invention may be embodied in other specific forms, without departing from its spirit or essential characteristics. The described embodiments are to be considered in all respects only as illustrative and not restrictive. The scope of the invention is, therefore, indicated by the appended claims rather than by the foregoing description. All changes that come within the meaning and range of equivalency of the claims are to be embraced within their scope.

I claim:

1. Imaging apparatus comprising a plurality of radiation-sensitive detectors that are arranged to define a curved imaging region at which incident radiation from a scene surrounding the detectors is detected and a processor for combining image information from the detectors to obtain an image of the surrounding scene.

2. Apparatus as claimed in claim 1 and wherein a curved panoramic image is obtained.

3. Apparatus as claimed in claim 1 and wherein a stereoscopic image is obtained.

4. Imaging apparatus comprising a plurality of radiation-sensitive detectors that are arranged to define a curved imaging region at which incident radiation from a scene surrounding the detectors is detected, the imaging region being extensive in a substantially curved plane and the field of view of the detectors being outward from the curved plane.

5. Apparatus as claimed in claim 4 and wherein the detectors comprise a linear array of imaging sensors arranged parallel to an axis and the array being movable along a curved path about the axis to define the imaging region.

6. Apparatus as claimed in claim 4 and wherein the detectors comprise a static curved array of imaging sensors.

7. Apparatus as claimed in claim 4 and wherein the detectors comprise a curved array of imaging sensors extensive in a substantially flat plane, the array being moveable in a direction normal to the substantially flat plane to define the curved imaging region.

8. Apparatus as claimed in claim 4 and wherein the imaging region is cylindrical.

9. Apparatus as claimed in claim 8 and wherein the detectors are arranged in a cylindrical, outward facing array and the array being moveable in a direction parallel to the cylindrical longitudinal axis.

10. Apparatus as claimed in claim 4 and wherein the imaging region is at least part-spherical.

11. Apparatus as claimed in claim 10 and wherein the detectors are arranged in a part-spherical array.

12. Apparatus as claimed in claim 4 and including a processor for combining image information from the detectors to obtain a curved panoramic image of the surrounding scene.

13. Apparatus as claimed in claim 4 and wherein the detectors comprise a plurality of CCD arrays.

14. Apparatus as claimed in claim 1 and wherein the imaging region is circular and is extensive in a substantially flat plane.

15. Apparatus as claimed in claim 1 and wherein the imaging region is elliptical and is extensive in a substantially flat plane.

16. Apparatus as claimed in claim 1 and including detectors arranged in a plurality of curved arrays, each array being extensive in a substantially flat plane, and the arrays being stacked parallel to one another in a direction normal to their planes.

17. Apparatus as claimed in claim 1 and wherein the detectors comprise a plurality of CCD arrays.

18. Apparatus as claimed in claim 1 and wherein the detectors are sensitive to visible radiation.

19. Apparatus as claimed in claim 1 and wherein the detectors are sensitive to infrared radiation.

20. Apparatus as claimed in claim 1 and wherein the image is a three-dimensional video image.

21. Surveillance equipment including imaging apparatus which comprises a plurality of radiation-sensitive detectors that are arranged to define a curved imaging region at which incident radiation from a scene surrounding the detectors is detected.

22. Equipment as claimed in claim 21 and including a processor for combining image information from the detectors to obtain a curved image of the surrounding scene.
